(19) United States
(12) Patent Application Publication
(10) Pub. No.: US 2005/0236034 A1
(43) Pub. Date: Oct. 27, 2005

(54) System and methods for generating electrical energy

(76) Inventors: Donald Styblo, Northfield Center, OH (US); Franklyn T. Bradshaw, Shaker Heights, OH (US)

Correspondence Address: HAHN LOESER & PARKS, LLP, One GOJO Plaza, Suite 300, AKRON, OH, 44311-1076, US

(21) Appl. No.: 11/060,214

(22) Filed: Feb. 17, 2005

Related U.S. Application Data
(60) Provisional application No. 60/545,579, filed on Feb. 17, 2004.

(51) Int. Cl. H01L 31/00

(52) U.S. Cl. 136/253

(57) ABSTRACT

A system and method for generating electrical energy are disclosed. A fuel cell generates a first source of electrical energy and thermal energy as a by-product. The thermal energy is presented to an advanced, thermophotovoltaic (A-TPV) converter as radiant infrared (IR) energy. The A-TPV converter captures and converts the radiant IR energy to a second source of electrical energy. The thermal energy may be generated directly as the radiant IR energy by the fuel cell itself, or may be converted, via conduction and/or convection, to the radiant IR energy using a infrared radiator approximating a black body radiator.

### CROSS-REFERENCE TO RELATED APPLICATIONS/INCORPORATION BY REFERENCE

This application claims priority to provisional U.S. Patent Application Ser. No. 60/545,579 filed on Feb. 17, 2005, and are incorporated herein by reference in their entirety.

### TECHNICAL FIELD

Certain embodiments of the present invention relate to systems and methods for generating electrical energy. More particularly, certain embodiments of the present invention relate to co-generation systems comprising a fuel cell and an advanced, thermophotovoltaic (A-TPV) converter and methods using such elements. The fuel cell generates a primary source of electrical energy and byproduct heat. The byproduct heat is captured and converted to a secondary source of electrical energy by the A-TPV converter.

### BACKGROUND OF THE INVENTION

In general, a fuel cell consists of two electrodes, an anode and a cathode, with an electrolyte between the electrodes. The preferred reactants in the fuel cell are hydrogen, as the fuel, and oxygen for which atmospheric air can suffice. The hydrogen fuel flows to the anode where it reacts with oxygen ions from the electrolyte, thereby releasing electrons to an external circuit. On the other side of the fuel cell, the oxidant, oxygen or air, flows to the cathode where it supplies the oxygen ions for the electrolyte by accepting electrons from the external circuit. The electrolyte conducts the ions between the electrodes, maintaining overall electrical charge balance. The flow of electrons in the external circuit uses or stores the useful power provided by the fuel cell.

A solid oxide fuel cell (SOFC) operates in an electrochemical process at about 1000° C., consuming basically hydrogen and oxygen and producing electrical energy, water, and heat. An SOFC is highly efficient in converting the potential energy of a fuel source to electrical energy and has minimal harmful emissions such as nitrous, sulfur oxide, and carbon dioxide.

The primary byproducts of an SOFC are heat, water, and carbon dioxide. In the best of circumstances, if the fuel source is pure hydrogen, the conversion efficiency of an SOFCreaches about 70%. That means that 30% of the energy from the fuel cell electrochemical process is high quality heat energy at about 1000° C. In contemporary fuel cells, the practical source of hydrogen comes from passing any one of many available types of hydrocarbon fuel through a reformer to extract a gas that is as close to pure hydrogen as possible.

A thermophotovoltaic (TPV) converter generates electricity from radiant heat energy by using low bandgap semiconductor devices containing p/n junctions. Radiant heat energy from the heat source enters the TPV device and produces “electron-hole” pairs by knocking some electrons out of their atomic orbit and leaving corresponding atoms with an electron deficit, holes. The p/n junction separates the electrons from the holes, creating an electrical potential difference and making the electrons available to do external work by an external electrical load.

Present state-of-the-art TPV devices, primarily made of silicon, are planar, narrow frequency semiconductor devices containing p/n junctions. The planar p/n junction covers the entire device cross-sectional area. Radiated heat energy from a heat source enters the TPV device and produces electron-hole pairs by knocking an electron out of its stable orbit in an atom configuration. In any electrical device, the power produced by the device is the product of voltage and current. In conventional TPV devices, it would seem desirable to increase the surface area to maximize the intercepted radiation from the heat source, thus increasing the current generated by the TPV device. However, the negative aspect of increasing the surface area of a TPV device is that the output voltage decreases as the surface area increases. In planar TPV technology, voltage and current are conflicting parameters in the effort to increase the power and efficiency of a device by intercepting all available radiated heat energy. Maximum energy conversion efficiency from heat energy to electrical energy for conventional TPV devices is 12% or less.

Although attempts have been made to convert the heat energy from a fuel cell system using a thermophotovoltaic (TPV) insulation disposed around at least a portion of a fuel cell, such attempts have not resulted in a commercially viable system for capturing and converting this energy to electrical energy.

Further limitations and disadvantages of conventional, traditional, and proposed approaches will become apparent to one of skill in the art, through comparison of such systems with the present invention as set forth in the remainder of the present application with reference to the drawings.

### BRIEF SUMMARY OF THE INVENTION

A first embodiment of the present invention provides a system for generating electrical energy. The system comprises a fuel cell to generate a first source of electrical energy and radiant infrared energy, as a by-product, over a broad infrared spectrum. The system further comprises a thermophotovoltaic (TPV) converter to capture and convert the radiant infrared energy to a second source of electrical energy.

A second embodiment of the present invention provides a system for generating electrical energy. The system comprises a fuel cell to generate a first source of electrical energy and heat, as a by-product. The system further comprises a black bodyinfrared (IR) emitter to capture the heat, via thermal conduction and/or thermal convection, and to radiate the heat as infrared (IR) energy. The system also includes an advanced thermophotovoltaic (A-TPV) converter to capture and convert the IR energy to a second source of electrical energy.

An embodiment of the present invention provides a first method to generate electrical energy. The method comprises generating a first source of electrical energy and radiant infrared (IR) heat energy using a fuel cell. The method further comprises generating a second source of electrical energy by capturing and converting the radiant IR energy to electricity using an advanced thermophotovoltaic (A-TPV) converter.

An embodiment of the present invention provides a second method to generate electrical energy. The method comprises generating a first source of electrical energy and heat using a fuel cell. The method further comprises capturing the heat, via thermal conduction and/or thermal convection, and converting the heat to radiant infrared (IR) energy using a black body infrared emitter. The method further comprises generating a second source of electrical energy by capturing and converting the radiant IR energy to electricity using an advanced thermophotovoltaic (A-TPV) converter.

These and other advantages and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1A illustrates an exemplary schematic block diagram of a first embodiment of a co-generation system, in accordance with various aspects of the present invention.

FIG. 1B illustrates the conversion of energy, by the co-generation system of FIG. 1A, from radiant IR energy to electrical energy, in accordance with an embodiment of the present invention.

FIG. 2 is a table illustrating the relative increase in radiated infrared energy from a body as the temperature of the body increases, in accordance with various aspects of the present invention.

FIG. 3 is a flowchart of an embodiment of a method to generate electrical energy using the co-generation system of FIG. 1A, in accordance with various aspects of the present invention.

FIG. 4A illustrates an exemplary schematic block diagram of a second embodiment of a co-generation system, in accordance with various aspects of the present invention.

FIG. 4B illustrates the conversion of energy, by the co-generation system of FIG. 4A, from thermal energy to electrical energy, in accordance with an embodiment of the present invention.

FIG. 5 is a flowchart of an embodiment of a method to generate electrical energy using the co-generation system of FIG. 4A, in accordance with various aspects of the present invention.

FIG. 6 illustrates an exemplary schematic block diagram of an alternative embodiment of a co-generation system operating according to the method of FIG. 5, in accordance with various aspects of the present invention.

FIG. 7 illustrates an exemplary schematic block diagram of a third embodiment of a co-generation system using a catalytic converter, in accordance with various aspects of the present invention.

### DETAILED DESCRIPTION OF THE INVENTION

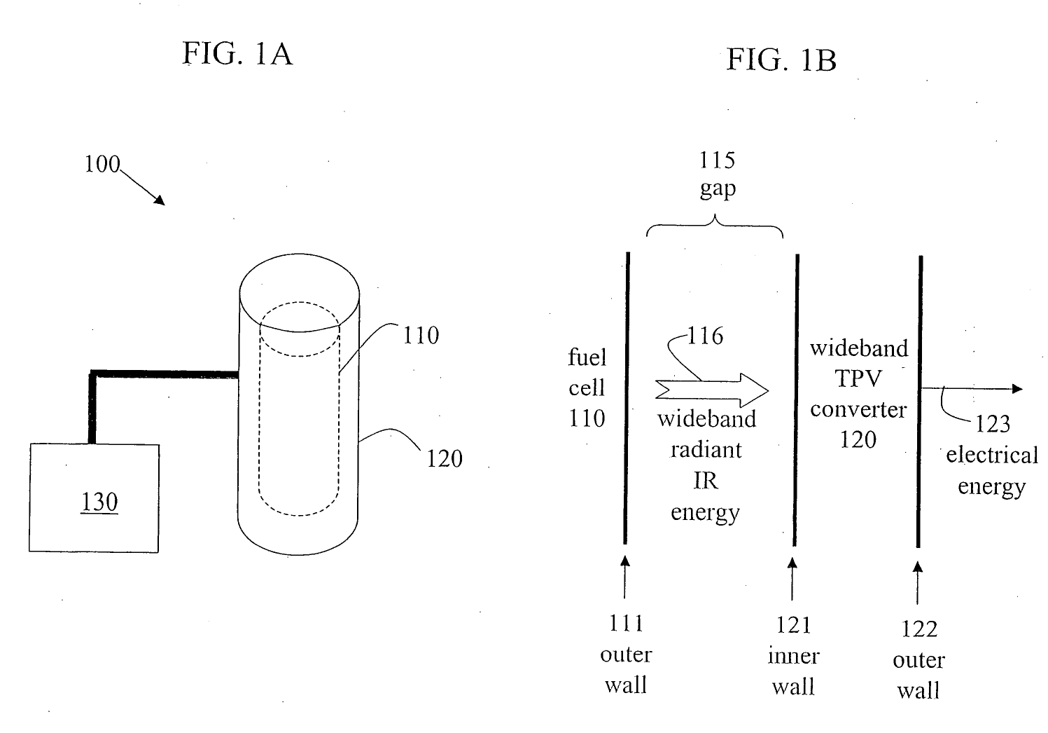

FIG. 1A. illustrates an exemplary schematic block diagram of a first embodiment of a co-generation system 100, in accordance with various aspects of the present invention. The co-generation system comprises a fuel cell 110, a A-TPV converter 120, spaced from fuel cell 110, and a heat sink 130. FIG. 1B illustrates the conversion of energy, by the co-generation system 100 of FIG. 1A, from radiant IR energy 116 to electrical energy 123, in accordance with an embodiment of the present invention. The fuel cell 110 serves as a first source of electrical energy and the TPV converter 120 serves as a second source of electrical energy.

The A-TPV converter 120 surrounds the fuel cell 110 but is not in physical contact with the fuel cell 110, via gap 115 between the fuel cell 110 and the A-TPV converter 120. The inner wall 121 of the TPV converter 120 is in close proximity, but not in contact with (e.g., not less than 0.1 mm) the outer wall 111 of the fuel cell 110. The outer wall 111 of the fuel cell 110 gives off radiant infrared (IR) energy 116, as a by-product, which is received by the inner wall 121 of the A-TPV converter 120. In accordance with an embodiment of the present invention, the bandwidth of the radiant IR energy is over an extended range, such as at least 1000 micrometers to about 100 nanometers.

In accordance with an alternative embodiment of the present invention, the A-TPV converter does not surround the entire fuel cell but, instead, is positioned in close proximity to a portion of the fuel cell. For example, the fuel cell and the A-TPV converter may be substantially rectangular in shape with a radiating surface of the fuel cell positioned 1 millimeter away from a receiving surface of the A-TPV converter.

The heat sink 130 is in thermal contact with the outer wall 122 of the A-TPV converter 120 in order to draw heat away from the A-TPV converter 120 via conduction to maintain the A-TPV at a lower temperature (e.g., 200° C.) than the fuel cell (e.g., 1000° C.). In accordance with an alternative embodiment of the present invention, the heat sink 130 is replaced with a flowing liquid such as cool gas or liquid which draws heat away from the outside surface of the A-TPV converter 120.

There are three possible modes of heat transfer which include conduction, convection, and radiation. Heat transfer always takes place between a heat source (i.e., a body at a higher temperature) and a heat sink (i.e., a body at a lower temperature) and, under passive circumstances, heat energy always flows from the heat source to the heat sink.

Conduction depends on having two bodies in physical contact (e.g., the outside of the A-TPV converter 120 and the heat sink 130), either directly or via a third body (i.e., a heat conductor between the two bodies). Convection depends on the mass transfer of a working fluid, liquid or gas, between the heat source and the heat sink to transfer the heat energy from the heat source to the heat sink. The process involves heat transfer from the heat source to molecules of the working fluid and the subsequent heat transfer from molecules of the working fluid to the heat sink.

Radiation is an electromagnetic process that does not depend on any contact or transfer of matter between the heat source (e.g., the fuel cell 110) and the heat sink (e.g., the advanced A-TPV converter 120). Every body emits heat energy in a portion of the electromagnetic spectrum. A body at a lower temperature will emit less radiant energy than a body at a higher temperature. As a result, a net heat transfer of radiant energy takes place from the heat source to the heat sink.

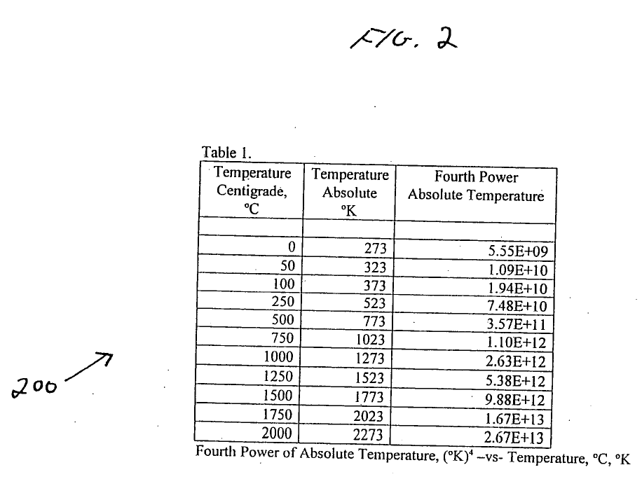

FIG. 2 is a table 200 illustrating the relative increase in radiated infrared energy from a body as the temperature of the body increases, in accordance with various aspects of the present invention. It can be seen from the table 200 that a body at 1000° C. radiates about three orders of magnitude more heat energy than the same body does at 0° C. Thermal radiation exhibits the same wavelike properties as light waves and radio waves. Each quantum or photon of radiant heat energy has a wavelength, λ, and a frequency, f. Heat radiation (i.e., radiant infrared radiation), which occurs primarily in the infrared portion of the electromagnetic spectrum, spans a wavelength spectrum from about 1000 micrometers to about 100 nanometers. Therefore, the heat energy spectrum covers about three to four orders of magnitude of wavelength.

A “black body” is a model for the perfect thermal radiator. A black body absorbs all radiant energy that reaches it and reflects nothing. Conversely, a black body is the most efficient emitter of radiant energy at any temperature. At a given temperature, all bodies will radiate heat energy across a portion of the electromagnetic spectrum. The energy is not distributed evenly to all wavelengths but has different energy flux at different wavelengths. At each temperature, a body will emit a unique distribution of energy at the continuum of different wavelengths. At any given temperature, a black body will emit the greatest energy at each wavelength that any heat source is capable of emitting at that temperature. In accordance with an embodiment of the present invention, the fuel cell 110 approximates a black body radiator to radiate infrared (IR) energy over a relatively wide range of IR frequencies.

Radiant heat energy reaches a body in the form of photons of infrared energy, each photon having a specific wavelength, λ, and corresponding frequency, f. Thermophotovoltaic (TPV) converters generate electricity from radiant heat energy by using low bandgap semiconductor devices containing p/n junctions. The A-TPV device 120 acts as a heat sink relative to the fuel cell 110 and is kept at a lower temperature than the heat source (i.e., fuel cell 110), using the heat sink 130, in order for net energy transfer to occur. Since TPV devices operate only from radiant heat based on an electromagnetic process, it is desirable to minimize heat transfer conduction and convection from the heat source (i.e., the fuel cell 110) to the heat sink (i.e., the advanced A-TPV converter 120) while maximizing heat transfer via radiation.

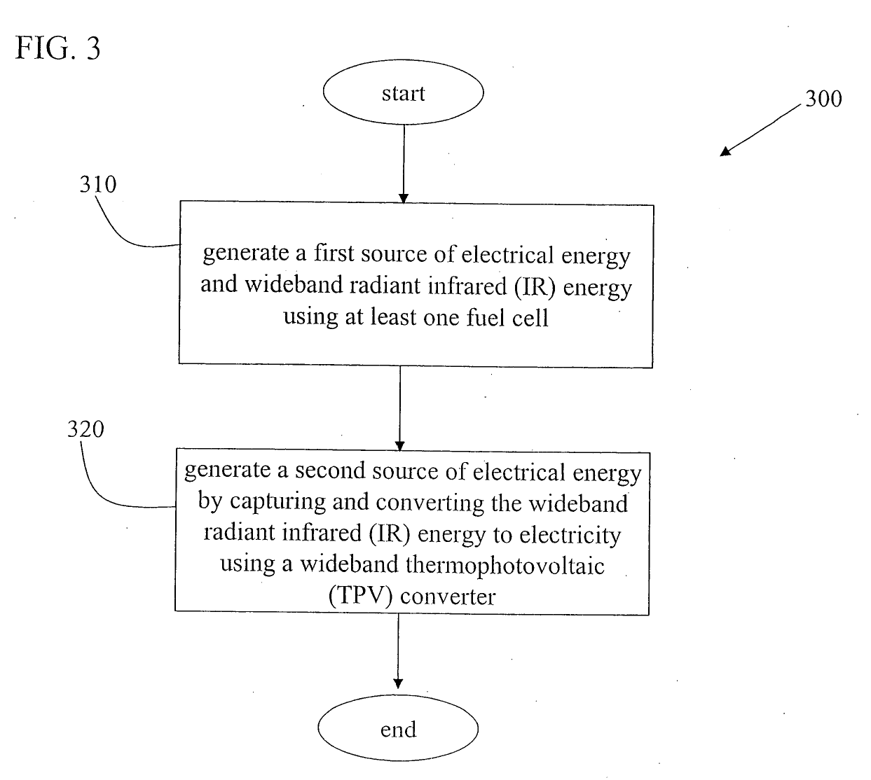

FIG. 3 is a flowchart of an embodiment of a method 300 to generate electrical energy using the co-generation system 100 of FIG. 1A, in accordance with various aspects of the present invention. In step 310, a first source of electrical energy and radiant infrared (IR) energy are generated using a fuel cell. In step 320, a second source of electrical energy is generated by capturing and converting the radiant IR energy to electricity using an advanced thermophotovoltaic (A-TPV) converter:

Radiation is most effective through a vacuum or a non-convective gas (air). These are also the most effective techniques to minimize conduction and convection. The A-TPV converter 120 is close to but not in physical contact with the radiant heat source (i.e., the fuel cell 110), preventing conduction. Opportunity for any gas (air) between the heat source and the A-TPV material to circulate is prevented so as to not transfer heat from the source to the A-TPV heat sink via convection. The A-TPV material itself is a body and, if allowed to increase in temperature, the amount of energy that the A-TPV material radiates back to the heat source will increase. An A-TPV heat sink is maintained at the lowest temperature that can practically be achieved, in accordance with an embodiment of the present invention (e.g., 200° C.).

Another reason to maintain the A-TPV material at the lowest practical temperature is based on the calculation of net heat energy transfer between two radiating bodies. The flux (rate of energy transfer per unit cross-sectional area) of energy radiating from a body, from the Stefan-Boltzmann law, varies as the 4^{th} power of the absolute body temperature, read in degrees Kelvin. Absolute zero, in degrees Kelvin, is 273 degrees below zero in degrees Centigrade.

Given the Stefan-Boltzmann law that the radiated flux varies as the 4^{th} power of the absolute temperature, the net heat transfer between the heat source and the A-TPV material (heat sink) varies as (T1⁴−T2⁴), where T1 is the absolute temperature of the heat source (e.g., a fuel cell) and T2 is the absolute temperature of the heat sink (e.g., the A-TPV material). In order to maximize energy conversion from heat to electricity, the receiving body (i.e., the A-TPV material) is to absorb the maximum amount of heat portion of the electromagnetic spectrum given off by the heat source (i.e., the fuel cell). In other words, it is desirable for the A-TPV converter 120 to have a response such that the A-TPV converter 120 can capture and convert all (or nearly all) of the radiant IR energy from the fuel cell 110.

In accordance with an embodiment of the present invention, an advanced TPV technology is used in the A-TPV converter 120, which breaks with the conventional planar practice of letting the p/n junction cover the entire cross-sectional frontal area of a A-TPV device. Instead, the p/n junction comprises a multitude of very small, uniformly spaced islands or dots on the inside face of the A-TPV converter 120. In such a configuration, the current level remains proportional to the surface area of the A-TPV converter 120, matching the behavior of planar TPV devices. The voltage, however, increases as the area of the p/n junction is decreased. With the proper selection of materials for both structural strength and conversion efficiency, the A-TPV converter 120, comprising Indium/Gallium/Arsenide (InGaAs) in accordance with an embodiment of the present invention, has an energy conversion efficiency far in excess of 12%. Advanced TPV configurations usable in accordance with the invention may be similar to that described in U.S. Pat. Nos. 5,571,339, 6,034,321, 6,482,672 and 6,660,928, which are hereby incorporated herein by reference, and Advanced TPV shall mean a TPV configuration having an energy conversion efficiency of 15% or above.

Conversion efficiencies of 30% have been demonstrated and higher conversion efficiencies are expected in such systems. One reason for the improved conversion efficiency is that A-TPV devices using the multitude of p/n junction dots have lower bandgaps than conventional TPV devices and, therefore, require less energy to knock an electron out of orbit in a stable atomic structure to create an electron-hole pair. As a result, these advanced A-TPV devices can absorb and convert lower energy heat photons than conventional TPV devices are able to, and over a wider band of wavelengths. Therefore, the advanced A-TPV device converts a greater amount of the radiant energy to electricity as desired relative to a conventional TPV device.

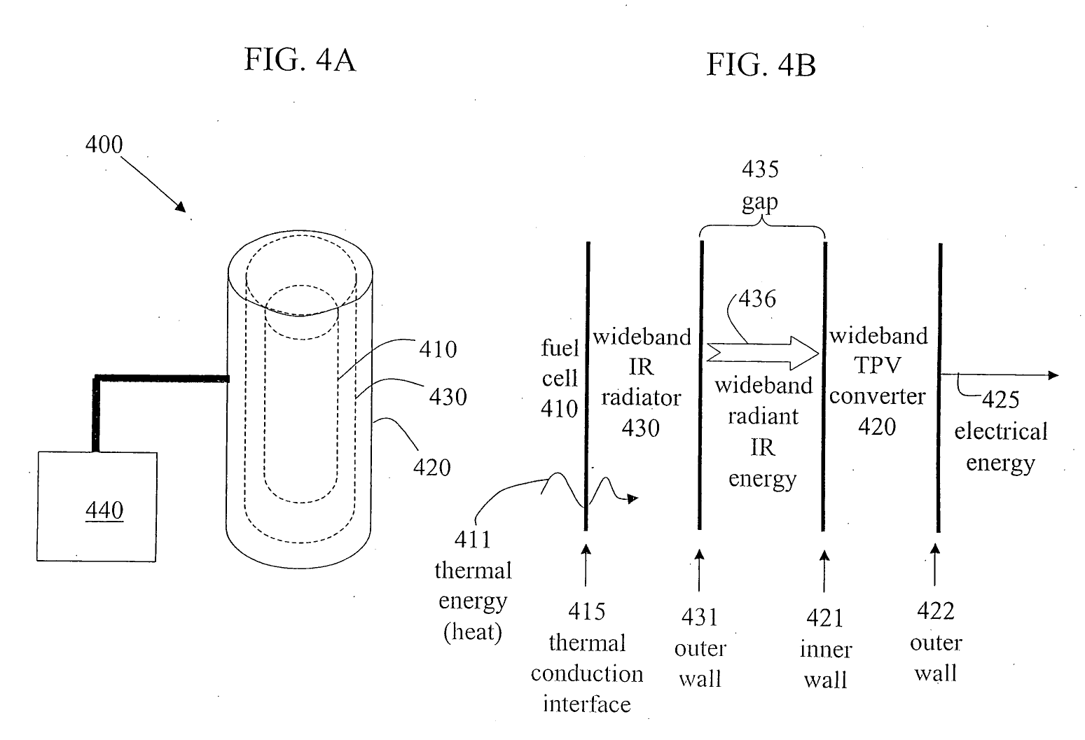

FIG. 4A illustrates an exemplary schematic block diagram of a second embodiment of a co-generation system 400, in accordance with various aspects of the present invention. The system 400 comprises a fuel cell 410, a A-TPV converter 420, and a IR radiator 430 positioned between the fuel cell 410 and the A-TPV converter 420. FIG. 4B illustrates the conversion of energy, by the co-generation system 400 of FIG. 4A, from thermal energy 411 to electrical energy 425, in accordance with an embodiment of the present invention.

The IR radiator 430 approximates a black body radiator and is not in physical contact with the A-TPV converter 420 but is in close proximity (e.g., not less than 0.1 mm) to the inner wall 421 of the A-TPV converter 420.

The surface of the fuel cell 410 is in physical contact with the IR radiator 430 forming a thermal conduction interface 415 such that the IR radiator 430 surrounds the fuel cell 410, in accordance with an embodiment of the present invention. Alternatively, the radiator 430 may be positioned to accept the output heated stream of exhaust gas from the fuel cell 410, and thereby convert heat by conduction from the exhaust. Thermal energy 411 is transferred from the surface or exhaust of the fuel cell 410 to the IR radiator 430 via thermal conduction across the interface 415. In accordance with an alternative embodiment of the present invention, heat is transferred from the surface of the fuel cell 410 to the IR radiator 430 via thermal convection (e.g., using a liquid between the fuel cell 410 and the IR radiator 430).

The IR radiator 430 converts the captured thermal energy 411 from the fuel cell 410 to radiant IR energy 436. The radiant IR energy 436 is transferred, via the process of electromagnetic radiation, to the inner wall 421 of the A-TPV converter 420 which surrounds the IR radiator 430. The A-TPV converter 420, using the advanced TPV technology previously described herein, captures the radiant IR energy 436 and converts it to electrical energy 425. The system 400 further comprises a heat sink 440 connected to the outer wall 422 of the A-TPV converter 420. The heat sink 440 is in physical contact with the outer wall 422 of the A-TPV converter 420 in order to draw heat away from the A-TPV converter 420 via conduction to maintain the lower temperature of the A-TPV (e.g., 200° C.). In accordance with an alternative embodiment of the present invention, the heat sink 440 is replaced with a flowing liquid such as cool air or water which draws heat away from the outer wall 422 of the A-TPV converter 420.

In accordance with an alternative embodiment of the present invention, the IR radiator does not surround the entire fuel cell but, instead, is positioned against a portion of the fuel cell (making thermal contact). Similarly, in accordance with an alternative embodiment of the present invention, the A-TPV converter does not surround the entire IR radiator but, instead, is positioned in close proximity to a portion of the IR radiator.

For example, the fuel cell, the IR radiator, and the A-TPV converter may all be substantially rectangular in shape. A surface of the IR radiator is butted up against a surface of the fuel cell such that physical thermal contact is made with the fuel cell. A receiving surface of the A-TPV converter is positioned 1 millimeter away from a radiating surface of the IR radiator such the radiant IR energy produced by the IR radiator is captured and converted by the A-TPV converter.

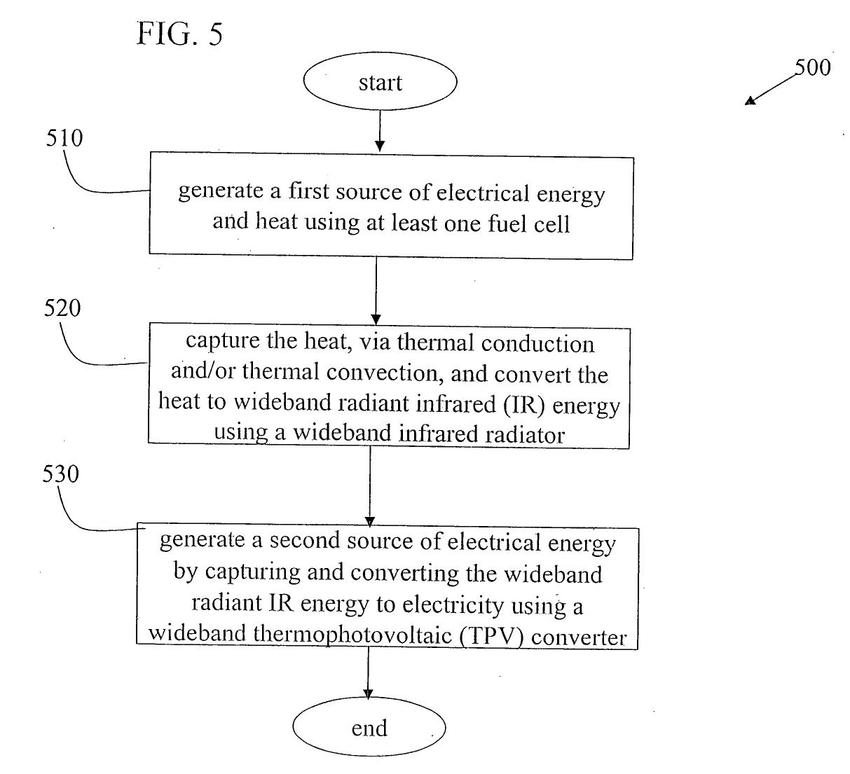

FIG. 5 is a flowchart of an embodiment of a method 500 to generate electrical energy using the co-generation system 400 of FIG. 4A, in accordance with various aspects of the present invention. In step 510, a first source of electrical energy and heat are generated using a fuel cell. In step 520, the heat is captured, via thermal conduction and/or thermal convection, by a infrared radiator, and converted to radiant IR energy. In step 530, a second source of electrical energy is generated by capturing and converting the radiant IR energy to electricity using a A-TPV converter.

In summary, embodiments of the present invention provide a system and method to generate electrical energy. An advanced, A-TPV converter is used to convert radiant infrared energy, generated (either directly or indirectly) by a fuel cell, to electrical energy. The fuel cell also generates electrical energy. The two sources of electrical energy (i.e., the fuel cell and the A-TPV converter) form an efficient co-generation system which may be used in many applications requiring a source of electrical energy.

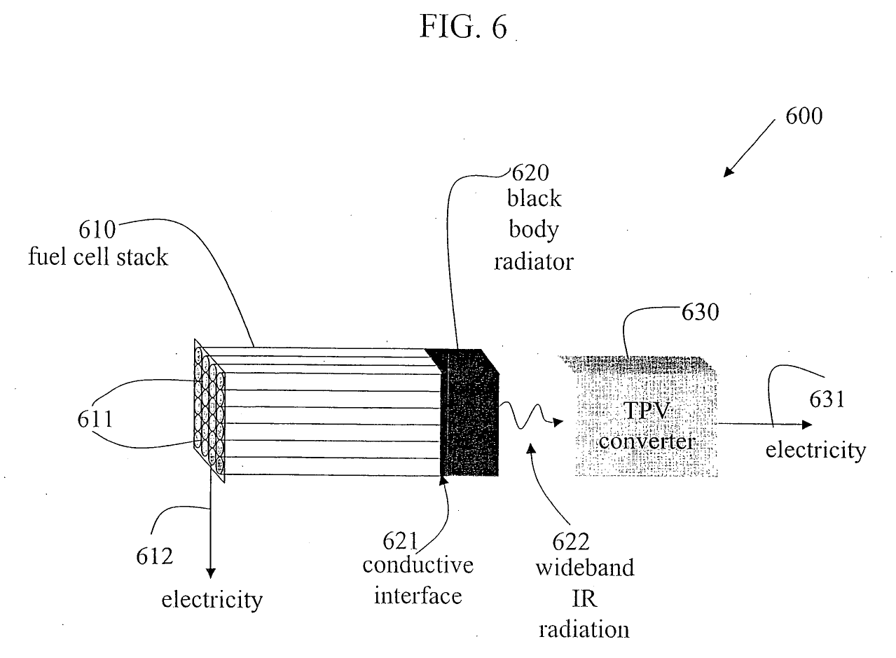

FIG. 6 illustrates an exemplary schematic block diagram of an alternative embodiment of a co-generation system 600 operating according to the method 500 of FIG. 5, in accordance with various aspects of the present invention. The system 600 comprises a fuel cell stack 610, a black body emitter 620 (i.e., an IR emitter approximating a black body radiator), and an advanced, A-TPV converter 630.

The fuel cell stack 610 comprises a plurality of tubular fuel cells 611. The tubular fuel cells 611 each comprise the basic elements of a fuel cell including an anode, a cathode, and an electrolyte in a concentric ring or coaxial configuration. The very center of each tubular fuel cell is hollow to allow air to flow through the center and over the cathode of each fuel cell 611. A fuel gas containing hydrogen is also be passed over the anodes of each fuel cell 611.

A surface of the fuel cell stack 610 and a first surface of the black body radiator 620 form an efficient conductive interface 621 (i.e., the two surfaces make physical contact). As electricity 612 and thermal energy are generated by the fuel cell stack 610, the thermal energy is conductively transferred, via the conductive interface 621, from the fuel cell stack 610 to the black body radiator 620.

As the black body radiator 620 heats up due to the transfer of the thermal energy, the black body radiator 620 gives off IR radiation 622. The A-TPV converter 630, being in close proximity to a second surface of the black body radiator 620, receives the IR radiation 622 and converts it to electricity 631. In accordance with an embodiment of the present invention, the black body radiator 620 comprises the material such as a silicon, carbide or other suitable material.

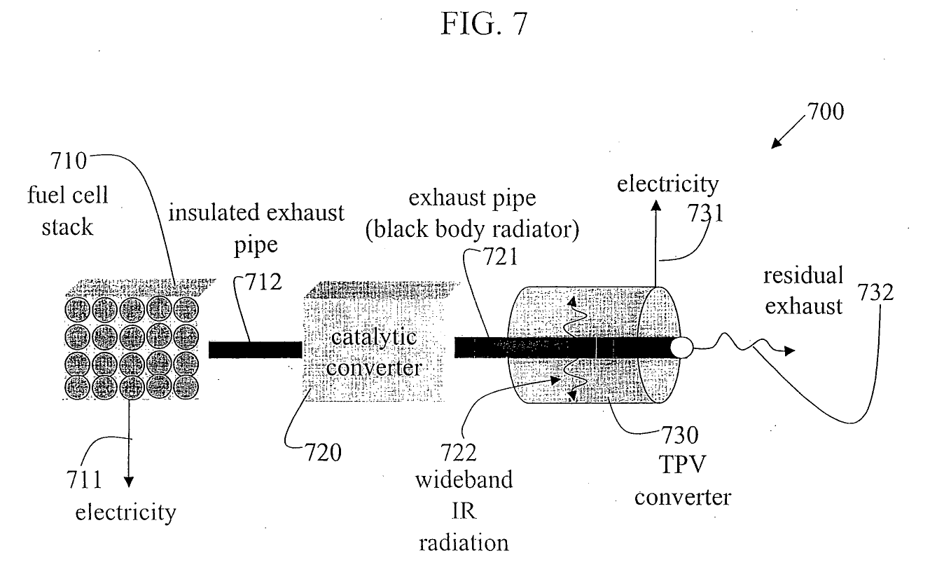

FIG. 7 illustrates an exemplary schematic block diagram of a third embodiment of a co-generation system 700 using a catalytic converter 720, in accordance with various aspects of the present invention. The system 700 comprises a fuel cell stack 710, an insulated exhaust pipe 712, a catalytic converter 720, a radiating exhaust pipe 721, and an advanced, A-TPV converter 730.

The insulated exhaust pipe 712 connects between the fuel cell stack 710 and the catalytic converter 720. The radiating exhaust pipe 721 connects between the catalytic converter 720 and the A-TPV converter 730. During operation, the fuel cell stack 710 generates electricity 711 and a heated exhaust of hydrocarbons and other by-products. As used herein, the term hydrocarbon is an organic compound composed of some combination of any of the elements of hydrogen, oxygen, and carbon (e.g., CO, CO₂, CH₄, H₂O, H₂). The heated exhaust is transferred from the fuel cell stack 710 to the catalytic converter 720 via the insulated exhaust pipe 712. The exhaust pipe 712 is insulated in order to transfer thermal energy from the fuel cell stack 710 to the catalytic converter 720 via the exhaust with minimal loss.

The catalytic converter 720 takes in the heated exhaust of hydrocarbons and other by-products and burns the hydrocarbons to produce a super-heated exhaust that exits through the radiating exhaust pipe 721. The superheated gas heats up the radiating exhaust pipe 721 from the inside out. As the radiating exhaust pipe 721 heats up, it acts as an approximate black body radiator and gives of wideband IR radiation 722. The A-TPV converter 730 is positioned around the radiating exhaust pipe 721 (but not in physical contact with the pipe 721) such that the A-TPV converter 730 receives the IR radiation 722 and converts it to electricity 731. Ideally, the vast majority of the thermal energy contained in the super-heated gas is converted to IR radiating energy 722 and a much cooler, residual exhaust 732 is given off at an end of the pipe 721.

In summary, embodiments of the present invention provide systems and methods to generate electrical energy. An advanced, A-TPV converter is used to convert radiant infrared energy, generated (either directly or indirectly) by a fuel cell (or fuel cell stack), to electrical energy. The fuel cell also generates electrical energy. The two sources of electrical energy (i.e., the fuel cell and the A-TPV converter) form an efficient co-generation system which may be used in many applications requiring a source of electrical energy.

While the invention has been described with reference to certain embodiments, it will be understood by those skilled in the art that various changes may be made and equivalents may be substituted without departing from the scope of the invention. In addition, many modifications may be made to adapt a particular situation or material to the teachings of the invention without departing from its scope. Therefore, it is intended that the invention not be limited to the particular embodiment disclosed, but that the invention will include all embodiments falling within the scope of the appended claims.

1. A system for generating electrical energy, said system comprising:
a fuel cell to generate a first source of electrical energy and radiant infrared (IR) energy, as a by-product, over a wide band of infrared frequencies; and
an advanced thermophotovoltaic (A-TPV) converter to capture and convert said radiant infrared energy to a second source of electrical energy.

2. The system of claim 1 further comprising a means to maintain a temperature differential between said A-TPV converter and said fuel cell.

3. The system of claim 1 wherein said fuel cell comprises a solid oxide fuel cell (SOFC).

4. The system of claim 1 wherein said A-TPV converter includes a plurality of small, uniformly spaced p/n junctions.

5. The system of claim 1 wherein a bandgap of said A-TPV converter is less than or equal to 0.5 electron volts (eV).

6. A system for generating electrical energy, said system comprising:
a fuel cell to generate a first source of electrical energy and heat as a by-product;
a IR radiator to capture said heat, via thermal conduction and/or thermal convection, and to radiate said heat as infrared (IR) energy; and
an advanced thermophotovoltaic (A-TPV) converter to capture and convert said radiated infrared (IR) energy to a second source of electrical energy.

7. The system of claim 6 further comprising a means to maintain a temperature differential between said A-TPV converter and said fuel cell.

8. The system of claim 6 wherein said fuel cell comprises a solid oxide fuel cell (SOFC).

9. The system of claim 6 wherein said A-TPV converter includes a plurality of small, uniformly spaced p/n junctions.

10. The system of claim 6 wherein a bandgap of said A-TPV converter is less than or equal to 0.5 electron volts (eV).

11. A method to generate electrical energy, said method comprising:
generating a first source of electrical energy and radiant infrared (IR) energy using a fuel cell; and
generating a second source of electrical energy by capturing and converting said radiant infrared (IR) energy to electricity using a thermophotovoltaic (A-TPV) converter.

12. The method of claim 11 further comprising maintaining a temperature differential between said fuel cell and said A-TPV converter such that said A-TPV converter is at a lower temperature than said fuel cell.

13. The method of claim 11 wherein a temperature of said fuel cell is about 1000° C.

14. The method of claim 11 wherein a temperature of said A-TPV converter is about 200° C.

15. The method of claim 11 wherein a bandwidth of said radiant IR energy is about 100 nanometers.

16. A method to generate electrical energy, said method comprising:
generating a first source of electrical energy and heat using a fuel cell;
capturing said heat, via thermal conduction and/or thermal convection, and converting said heat to radiant infrared (IR) energy by using a infrared radiator; and
generating a second source of electrical energy by capturing and converting said radiant IR energy to electricity using an advanced thermophotovoltaic (A-TPV) converter.

17. The method of claim 16 further comprising maintaining a temperature differential between said fuel cell and said A-TPV converter such that said A-TPV converter is at a lower temperature than said fuel cell.

18. The method of claim 16 wherein a temperature of said fuel cell is about 1000° C.

19. The method of claim 16 wherein a temperature of said A-TPV converter is about 200° C.

20. The method of claim 16 wherein a bandwidth of said radiant IR energy is about 100 nanometers.
